(19) United States
(12) Patent Application Publication
(10) Pub. No.: US 2011/0155438 A1
(43) Pub. Date: Jun. 30, 2011

(54) Multilayer Wiring Substrate

(75) Inventors: Tatsuya ITO, Kakamiganhara-shi (JP); Tetsuo SUZUKI, Niwa-gun (JP); Takuya HANDO, Inuyama-shi (JP); Shinnosuke MAEDA, Nagoya-shi (JP); Atsuhiko SUGIMOTO, Kagamigahara-shi (JP); Satoshi HIRANO, Chita-gun (JP)

(73) Assignee: NGK SPARK PLUG CO., LTD., Nagoya-shi (JP)

(21) Appl. No.: 12/978,750

(22) Filed: Dec. 27, 2010

(30) Foreign Application Priority Data
Dec. 28, 2009 (JP) 2009-296910

(51) Int. Cl. H05K 1/11

(52) U.S. Cl. 174/261

(57) ABSTRACT

A multilayer wiring substrate has a multilayer wiring laminate portion in which a plurality of resin insulation layers made primarily of the same resin insulation material, and a plurality of conductive layers are laminated alternately. A plurality of first-main-surface-side connection terminals are disposed on one side of the laminate structure where a first main surface thereof is present, and a plurality of second-main-surface-side connection terminals being disposed on an other side of the laminate structure where a second main surface thereof is present. The plurality of conductive layers are formed in the plurality of resin insulation layers and interconnected by means of via conductors whose diameters increase toward the first main surface or the second main surface. The plurality of first-main-surface-side connection terminals comprising at least two types of terminals for connection of different articles-to-be-connected. Top surfaces of the plurality of first-main-surface-side connection terminals differ in height according to types of the articles-to-be-connected.

### CROSS REFERENCE TO RELATED APPLICATIONS

The present application claims priority from Japanese Patent Application No. 2009-296910, which was filed on Dec. 28, 2009, the disclosure of which is herein incorporated by reference in its entirety.

### TECHNICAL FIELD

The present invention relates to a multilayer wiring substrate having a laminate structure in which a plurality of resin insulation layers made primarily of the same resin insulation material, and a plurality of conductive layers are laminated alternately in multilayer arrangement, and not having a so-called substrate core.

### BACKGROUND ART

In association with recent increasing tendency toward higher operation speed and higher functionality of semiconductor integrated circuit devices (IC chips) used as, for example, microprocessors of computers, the number of terminals increases, and the pitch between the terminals tends to become narrower. Generally, a large number of terminals are densely arrayed on the bottom surface of an IC chip and flip-chip-bonded to terminals provided on a motherboard. However, since the terminals of the IC chip differ greatly in pitch from those of the motherboard, difficulty is encountered in bonding the IC chip directly onto the motherboard. Thus, according to an ordinarily employed method, a semiconductor package configured such that the IC chip is mounted on an IC chip mounting wiring substrate is fabricated, and the semiconductor package is mounted on the motherboard.

The IC chip mounting wiring substrate which partially constitutes such a semiconductor package is practicalized in the form of a multilayer substrate configured such that a build-up layer is formed on the front and back surfaces of a substrate core. The substrate core used in the multilayer wiring substrate is, for example, a resin substrate (glass epoxy substrate) formed by impregnating reinforcement fiber with resin. Through utilization of rigidity of the substrate core, resin insulation layers and conductive layers are laminated alternately on the front and back surfaces of the substrate core, thereby forming respective build-up layers. In the multilayer wiring substrate, the substrate core serves as a reinforcement and is formed very thick as compared with the build-up layers. Also, the substrate core has conductor lines (specifically, through-hole conductors, etc.) extending therethrough for electrical communication between the build-up layers formed on the front and back surfaces.

In recent years, in association with implementation of high operation speeds of semiconductor integrated circuit devices, signal frequencies to be used have become those of a high frequency band. In this case, the conductor lines which extend through the substrate core serve as sources of high inductance, leading to the transmission loss of high-frequency signals and the occurrence of circuitry malfunction and thus hindering implementation of high operation speed. In order to solve this problem, a multilayer wiring substrate having no substrate core is proposed (refer to, for example, Patent Document 1). This multilayer wiring substrate does not use a substrate core, which is relatively thick, thereby reducing the overall wiring length. Thus, the transmission loss of high-frequency signals is lowered, whereby a semiconductor integrated circuit device can be operated at high speed.

Patent Document 1: Japanese Patent Application Laid-open (kokai) No. 2009-117703

### BRIEF SUMMARY OF THE INVENTION

Patent Document 1 mentioned above proposes a multilayer wiring substrate in which, in addition to connection terminals for an IC chip, connection terminals for electronic components, such as chip capacitors, are formed on an IC chip mounting surface. That is, a plurality of types of connection terminals for connection of different articles-to-be-connected are formed on the IC chip mounting surface of the multilayer wiring substrate. The plurality of types of connection terminals are formed such that their surfaces are flush with the surface of an outermost insulation resin layer on the side where the IC chip mounting surface is present. When the connection terminals are formed flush with the surface of the outermost insulation resin layer, difficulty may be encountered in connecting a plurality of types of components. Specifically, for example, in the case where solder bumps are to be formed on the connection terminals for an IC chip by use of fine solder balls, if the surfaces of the connection terminals for the IC chip are flush with the surface of the insulation resin layer, difficulty is encountered in disposing the solder balls on the connection terminals. Also, in the case where a chip capacitor, etc. are to be soldered to the connection terminals for electronic components, solder fillets can be formed only on the top surfaces of the connection terminals, potentially resulting in lack of connection strength.

The present invention has been conceived in view of the above problems, and an object of the invention is to provide a multilayer wiring substrate allowing reliable connection thereto of a plurality of articles-to-be-connected of different types.

A means for solving the above problems is a multilayer wiring substrate having a laminate structure in which a plurality of resin insulation layers made primarily of the same resin insulation material, and a plurality of conductive layers are laminated alternately in multilayer arrangement. A plurality of first-main-surface-side connection terminals are disposed on one side of the laminate structure where a first main surface thereof is present. A plurality of second-main-surface-side connection terminals are disposed on an other side of the laminate structure where a second main surface thereof is present. The plurality of conductive layers are formed in the plurality of resin insulation layers and interconnected by means of via conductors whose diameters increase toward the first main surface or the second main surface. The plurality of first-main-surface-side connection terminals include at least two types of terminals for connection of different articles-to-be-connected, and top surfaces of the plurality of first-main-surface-side connection terminals differ in height according to types of the articles-to-be-connected.

According to the invention mentioned above, the multilayer wiring substrate is formed such that a plurality of the resin insulation layers made primarily of the same resin insulation material, and a plurality of the conductive layers are laminated alternately, and assumes the form of a coreless wiring substrate having no substrate core. In the multilayer wiring substrate, a plurality of the first-main-surface-side connection terminals formed on the first main surface side differ in top-surface height according to types of the articles-to-be-connected. Thus, the articles-to-be-connected can be reliably connected to the first-main-surface-side connection terminals according to the types of the articles-to-be-connected.

Preferably, one type of the plurality of first-main-surface-side connection terminals are IC-chip connection terminals for connection of an IC chip, and an other type of the plurality of first-main-surface-side connection terminals are passive-component connection terminals for connection of a passive component. The passive-component connection terminals are greater in area (i.e., have a larger outer surface area) than the IC-chip connection terminals, and, when a surface of a resin insulation layer serving as an outermost layer and exposed as the first main surface is defined as a reference surface, top surfaces of the passive-component connection terminals are higher in height than (i.e., protrude from) the reference surface, and top surfaces of the IC-chip connection terminals are identical in height to (i.e., flush with) or lower in height than (i.e., recessed from) the reference surface. In this case, since the top surfaces of the passive-component connection terminals are higher in height than the reference surface, solder fillets for connection of the passive component can be reliably formed on the passive-component connection terminals. Also, since the top surfaces of the IC-chip connection terminals are identical in height to or lower in height than the reference surface, solder bumps for flip-chip bonding of the IC chip can be reliably formed on the IC-chip connection terminals.

Preferably, the resin insulation layer serving as an outermost layer and exposed as the first main surface of the laminate structure has openings, and the IC-chip connection terminals are formed in the openings such that the top surfaces of the IC-chip connection terminals are lower in height than (i.e., recessed from) the reference surface. Through employment of this configuration, depressions are formed at the positions of the IC-chip connection terminals. Thus, relatively fine solder balls can be readily positioned on the IC-chip connection terminals within the openings. Therefore, solder bumps can be reliably formed on the IC-chip connection terminals.

Preferably, walls defining the openings have roughened wall surfaces, the IC-chip connection terminals are composed primarily of a copper layer, and the copper layer fills the openings while following the roughened wall surfaces. Through such formation of the IC-chip connection terminals, adhesion between the IC-chip connection terminals and the resin insulation layer can be enhanced. As a result, separation of the IC-chip connection terminals or a like problem can be reliably prevented, whereby the reliability of the multilayer wiring substrate can be enhanced.

Preferably, one type of the plurality of first-main-surface-side connection terminals are IC-chip connection terminals for connection of an IC chip, an other type of the plurality of first-main-surface-side connection terminals are passive-component connection terminals for connection of a passive component, and the passive-component connection terminals are greater in area (i.e., have a larger outer surface area) than the IC-chip connection terminals. Further, each passive-component connection terminal has a structure in which a plating layer of a material other than copper covers a top surface and a side surface of a portion of a copper layer which portion is a main constituent of the passive-component connection terminals. Still further, each IC-chip connection terminal has a structure in which a plating layer of a material other than copper covers only a top surface of a portion of the copper layer which portion is a main constituent of the IC-chip connection terminals. Through employment of this configuration, relatively large solder fillets can be reliably formed on the top surfaces and the side surfaces of the passive-component connection terminals. Also, solder bumps can be reliably formed on the top surfaces of the IC-chip connection terminals. The interval between the passive-component connection terminals is greater than that between the IC-chip connection terminals, and the passive-component connection terminals have a relatively large size; thus, by means of the solder fillets formed on the top surfaces and the side surfaces of the passive-component connection terminals, the passive components can be reliably soldered to the passive-component connection terminals with a sufficient strength. Meanwhile, since the interval between the IC-chip connection terminals is small, a lateral expansion of solder bumps from the side surfaces of the IC-chip connection terminals raises a problem of a short circuit between the IC-chip connection terminals. By contrast, in the present invention, since solder bumps are formed only on the top surfaces of the IC-chip connection terminals, the solder bumps do not expand laterally, so that a short circuit between the IC-chip connection terminals can be avoided.

Preferably, each passive-component connection terminal has a trapezoidal cross section such that a bottom surface of each passive-component connection terminal is greater in area than a top surface of each passive-component connection terminal. The passive-component connection terminals are in contact with the outermost resin insulation layer at their bottom surfaces. Thus, through impartment of such a trapezoidal cross section to the passive-component connection terminals, the contact area between the resin insulation layer and the bottom surfaces of the passive-component connection terminals increases, whereby the strength of the passive-component connection terminals can be sufficiently ensured.

In accordance with one implementation, one type of the plurality of first-main-surface-side connection terminals are greater in area (i.e., have a larger outer surface area) than an other type of the plurality of first-main-surface-side connection terminals. Then, the one type of the plurality of first-main-surface-side connection terminals having a greater area are higher in top-surface height than the other type of first-main-surface-side connection terminals having a smaller area. Through employment of this height feature, a component having a large connection area and a component having a small connection area can be reliably connected to top surfaces of the first-main-surface-side connection terminals of different heights.

The via conductors formed in the plurality of resin insulation layers may be shaped such that a diameter thereof increases along a direction from the second main surface to the first main surface. By contrast, the via conductors formed in the plurality of resin insulation layers may also be shaped such that a diameter increases along a direction from the first main surface to the second main surface. Through employment of this diametral feature, a coreless wiring substrate having no substrate core can be reliably manufactured.

Preferably, the plurality of resin insulation layers are formed of a hardened resin insulation material that is not photocurable; for example, the same build-up material made primarily of a hardened thermosetting resin insulation material. In this case, since the outermost resin insulation layer on which the connection terminals are formed is formed of the same build-up material having excellent electrical insulation performance as that used to form the inner resin insulation layers, the interval between the connection terminals can be narrowed, so that the multilayer wiring substrate can be further integrated.

The second main surface of the laminate structure may have a solder resist film provided thereon and made primarily of a hardened photocurable resin insulation material. The employed solder resist film can protect the second main surface, thereby preventing potential damage to the second-main-surface-side connection terminals in the course of conveyance or the like. Preferably, a material having a low rigidity or a material having a low Young's modulus is used to form the solder resist film. The use of such a material can restrain warpage of the multilayer wiring substrate which could otherwise result from the difference in thermal expansion coefficient between the resin insulation layers and the solder resist film.

A solder resist film made primarily of a hardened photocurable resin insulation material may be provided in a region around an IC-chip mounting region on the first main surface of the laminate structure. Since the thus-provided solder resist film forms a level difference between the IC-chip mounting region and its surrounding region, there can be avoided a problem that flux and an underfill material charged into the IC-chip mounting region protrude from the IC-chip mounting region.

The following configuration may be employed: one type of the plurality of first-main-surface-side connection terminals are IC-chip connection terminals for connection of an IC chip, and an other type of the plurality of first-main-surface-side connection terminals are passive-component connection terminals for connection of a passive component, the passive-component connection terminals being greater in area than the IC-chip connection terminals; the plurality of second-main-surface-side connection terminals are motherboard connection terminals for connection of a motherboard; the motherboard connection terminals are greater in area (i.e., have a larger outer surface area) than the IC-chip connection terminals and the passive-component connection terminals; and, when a surface of a resin insulation layer serving as an outermost layer and exposed as the second main surface is defined as a reference surface, outer surfaces of the motherboard connection terminals are higher in height than (i.e., protrude from) the reference surface. Through employment of this configuration, the motherboard connection terminals can be reliably connected to a motherboard.

Preferably, each motherboard connection terminal has a trapezoidal cross section, a top surface (i.e., contact surface) of each motherboard connection terminal in contact with the resin insulation layer is greater in area than a bottom surface (i.e., an outer surface) of each motherboard connection terminal opposite the top surface (i.e., contact surface). Through impartment of such a trapezoidal cross section to the motherboard connection terminals, the contact area between the resin insulation layer and the top surfaces of the motherboard connection terminals increases, whereby the strength of the motherboard connection terminals can be sufficiently ensured.

Not only the motherboard connection terminals for connection of a motherboard serving as the article-to-be-connected but also the IC-chip connection terminals for connection of an IC chip serving as the article-to-be-connected, or the passive-component connection terminals for connection of a passive component serving as the articles-to-be-connected may be present on the second main surface side of the laminate structure. Through employment of such a configuration, the IC chip or the passive components can be mounted on the second main surface where the motherboard is connected, so that the multilayer wiring substrate can be further integrated.

A material for the resin insulation layers of the laminate structure can be selected as appropriate in consideration of electrical insulation performance, heat resistance, humidity resistance, etc. Preferred examples of a polymeric material used to form the resin insulation layers include thermosetting resins, such as epoxy resin, phenol resin, urethane resin, silicone resin, and polyimide resin; and thermoplastic resins, such as polycarbonate resin, acrylic resin, polyacetal resin, and polypropylene resin. Additionally, there may be used a composite material consisting of any one of these resins, and glass fiber (glass woven fabric or glass nonwoven fabric) or organic fiber, such as polyamide fiber, or a resin-resin composite material in which a three-dimensional network fluorine-containing resin base material, such as continuously porous PTFE, is impregnated with a thermosetting resin, such as epoxy resin.

The conductive layers and the connection terminals of the laminate structure are made primarily of copper and are formed by a known process, such as a subtractive process, a semi-additive process, or a fully-additive process. Specifically, for example, etching of a copper foil, electroless copper plating, or copper electroplating is applied. Also, the conductive layers and the connection terminals can be formed by forming a thin film by sputtering, CVD, or a like process, followed by etching. Alternatively, the conductive layers and the connection terminals can be formed through application of conductive paste or the like by printing.

A method of manufacturing the multilayer wiring substrate includes a build-up step of alternately laminating a plurality of resin insulation layers made of the same insulation material, and a plurality of conductive layers in multilayer arrangement on a side of a base material where a pair of metal foils are laminated in a mutually separable condition, thereby forming a laminate structure; a full-panel plating step of performing plating over the entire surface of an outermost resin insulation layer of the laminate structure, thereby forming filled-via conductors in the resin insulation layer and forming a full-surface plating layer which covers the entire surface of the resin insulation layer; a base-material removing step of, after the full-panel plating step, separating the pair of metal foils from each other, thereby removing the base material and exposing the metal foil; and a connection-terminal forming step of, after the base-material removing step, patterning the full-surface plating layer and the metal foil on the laminate structure by a subtractive process, thereby forming the first-main-surface-side connection terminals and the second-main-surface-side connection terminals. In this manufacturing method, the laminate structure after the base-material removing step is in a condition in which the full-surface plating layer is formed on one side, and the metal foil is formed on the other side. In this case, similar to the case of manufacture of an ordinary wiring substrate, in the connection-terminal forming step, the first main surface and the second main surface can be simultaneously subjected to patterning by a subtractive process for simultaneous formation of the connection terminals on the first and second main surfaces.

Preferably, in the build-up step, in formation of the outermost resin insulation layer of the laminate structure, there is used a thin-copper-foil-clad build-up material having a thin copper foil formed on its surface, and made primarily of a resin insulation material that is not photocurable, and laser drilling is performed on the laminated thin-copper-foil-clad build-up material, thereby forming openings for forming filled-via conductors therein; and after the build-up step and before the full-panel plating step, a desmear step is performed for removing smears from inside the openings. According to this manufacturing method, in the desmear step, since the surface of the outermost resin insulation layer is covered with the thin copper foil, the surface of the resin insulation layer is not roughened by desmear treatment. Also, the surface roughness of the outermost resin insulation layer is determined through transfer of the roughness of a contact surface of the thin copper foil to the surface of the outermost resin insulation layer. Thus, the surface of the outermost resin insulation layer of the laminate structure can have a uniform surface roughness, and flux and an underfill material can be provided in an appropriate condition on the surface.

Another method of manufacturing the multilayer wiring substrate includes a build-up step of alternately laminating a plurality of resin insulation layers made of the same insulation material, and a plurality of conductive layers in multilayer arrangement on a side of a base material where a pair of metal foils are laminated in a mutually separable condition, thereby forming a laminate structure, and performing laser drilling on the outermost resin insulation layer of the laminate structure, thereby forming a plurality of openings; a full-surface plating step of forming, by electroless plating, a full-surface plating layer which covers the outermost resin insulation layer and the interiors of the plurality of openings; a filled-via-conductor forming step of forming filled-via conductors in a part of the plurality of openings through selective pattern plating in a condition in which a plating resist film is formed on the first main surface; a full-surface-plating-layer removing step of, after the filled-via-conductor forming step, removing the full-surface plating layer while leaving the filled-via conductors intact, through patterning by a semi-additive process; a base-material removing step of, after the full-surface-plating-layer removing step, separating the pair of metal foils from each other, thereby removing the base material and exposing the metal foil; and a connection-terminal forming step of, after the base-material removing step, patterning the metal foil on the laminate structure by a subtractive process, thereby forming the second-main-surface-side connection terminals. Through employment of this method of manufacturing the multilayer wiring substrate, a plurality of the openings having uniform depth can be reliably formed in the resin insulation layer serving as an outermost layer and exposed on the first main surface. Therefore, relatively fine solder balls can be readily positioned on the IC-chip connection terminals within the openings, so that solder bumps can be more reliably formed on the IC-chip connection terminals.

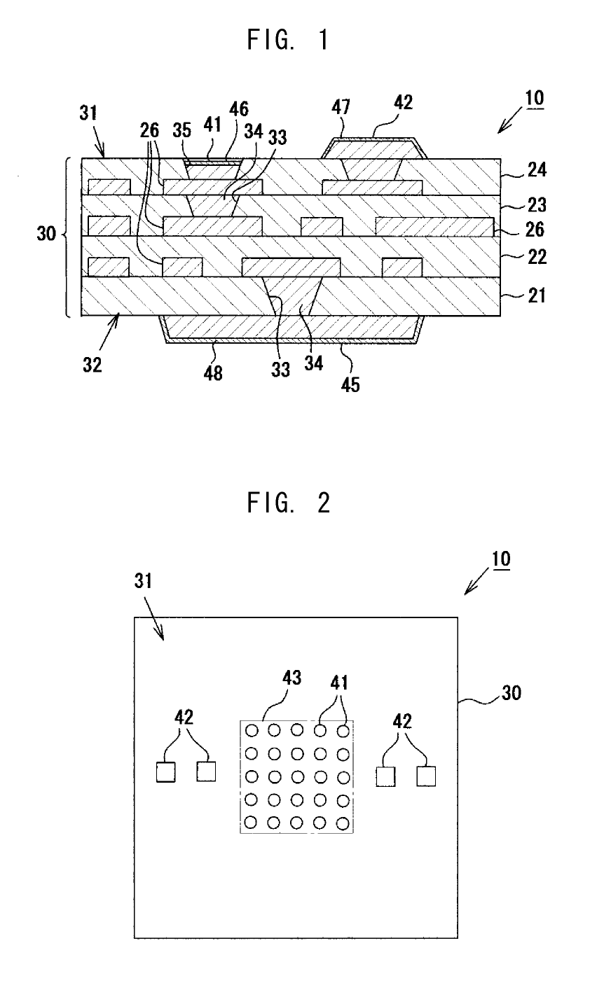

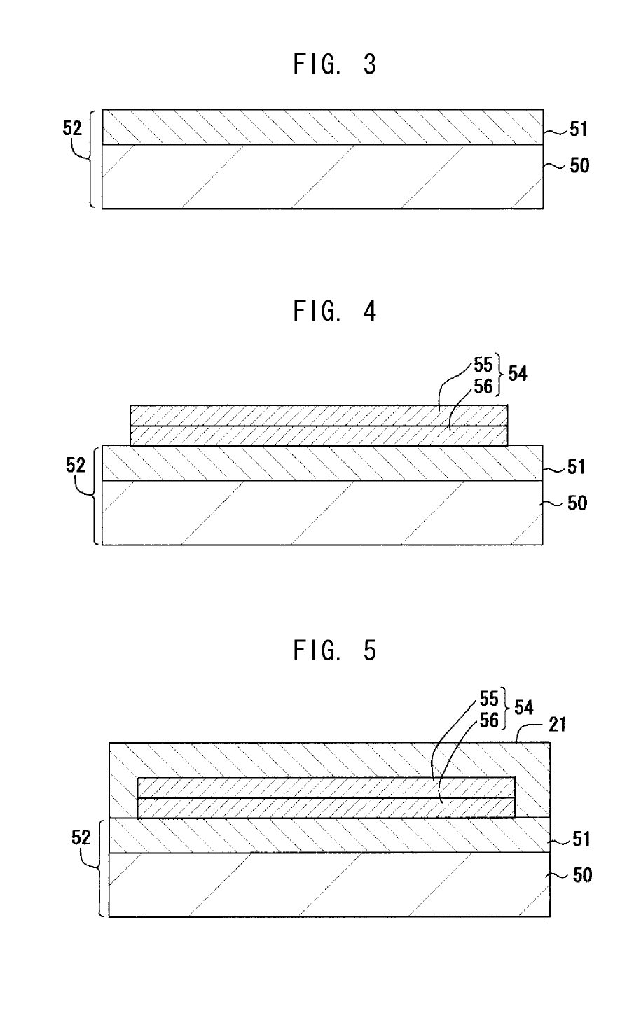

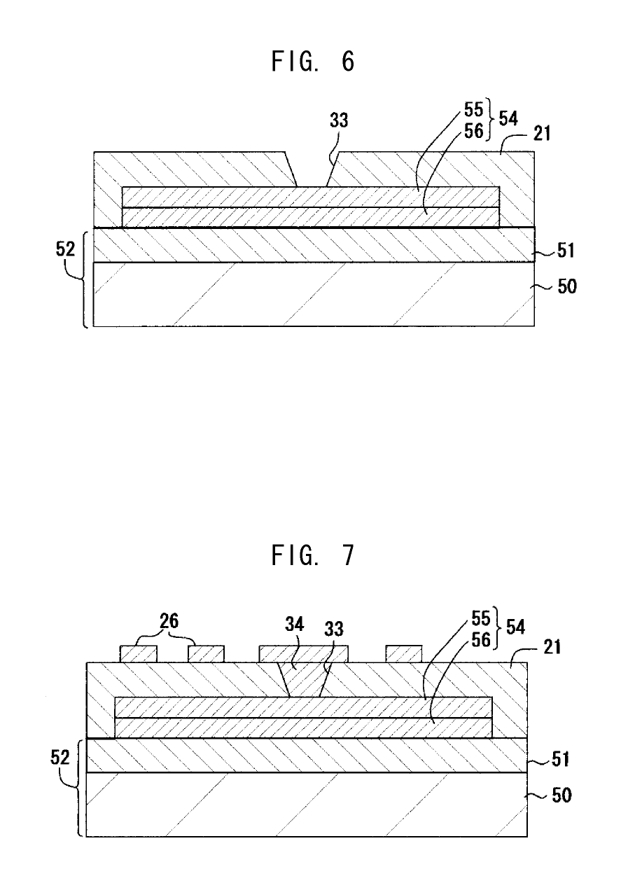

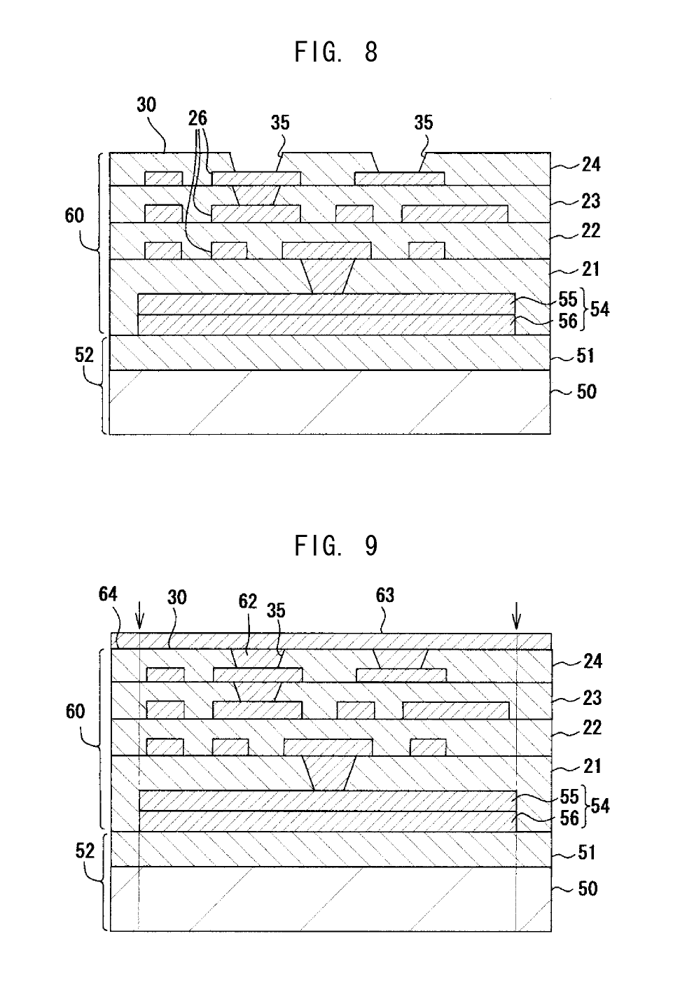

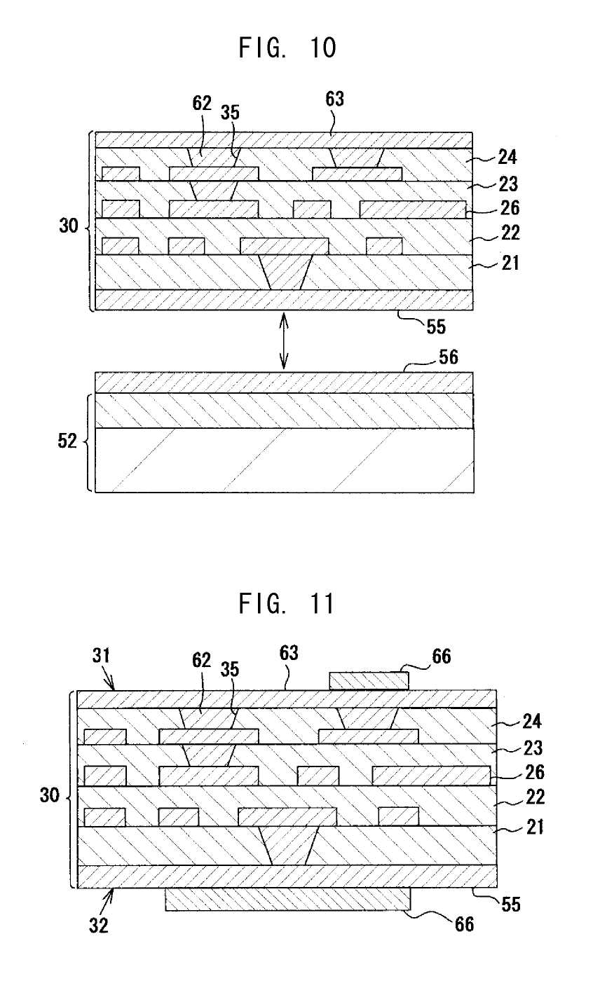

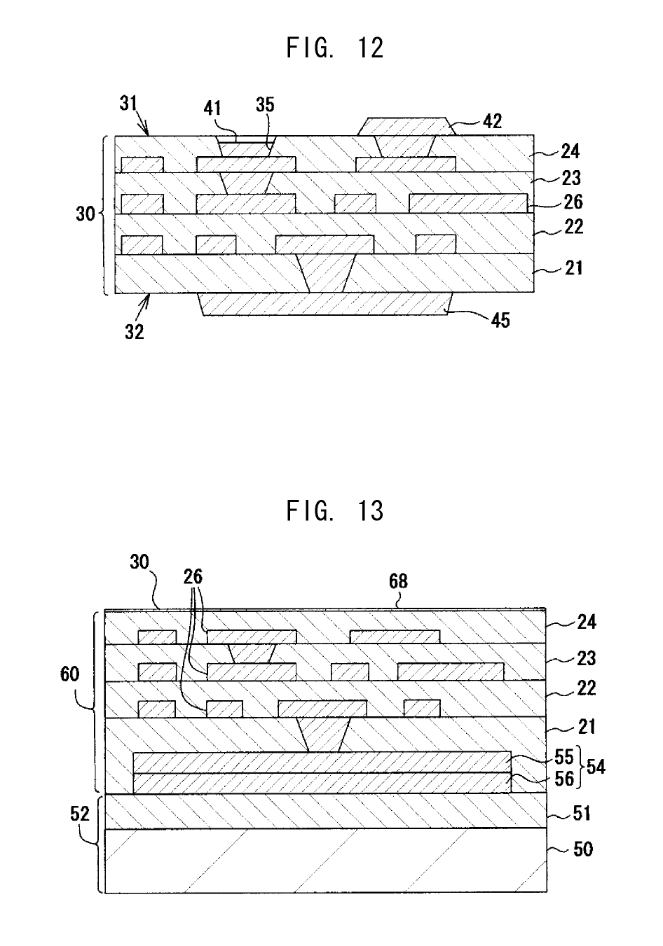

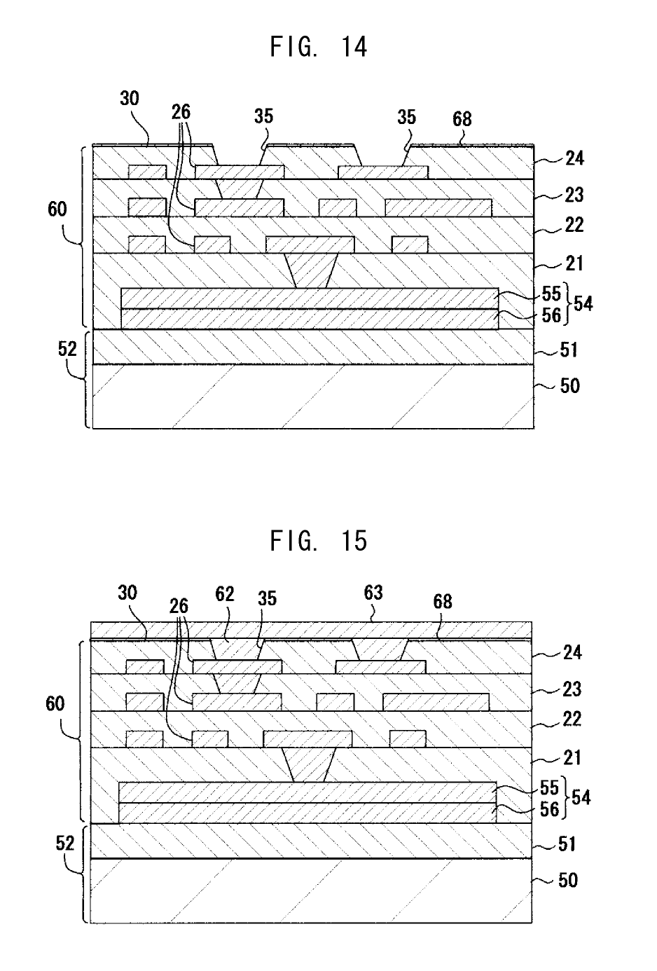

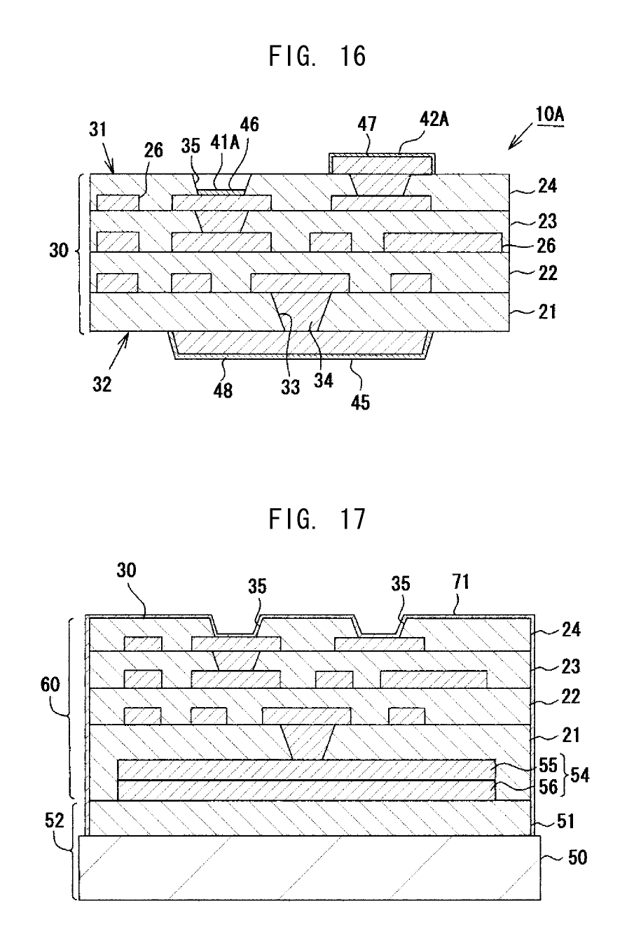

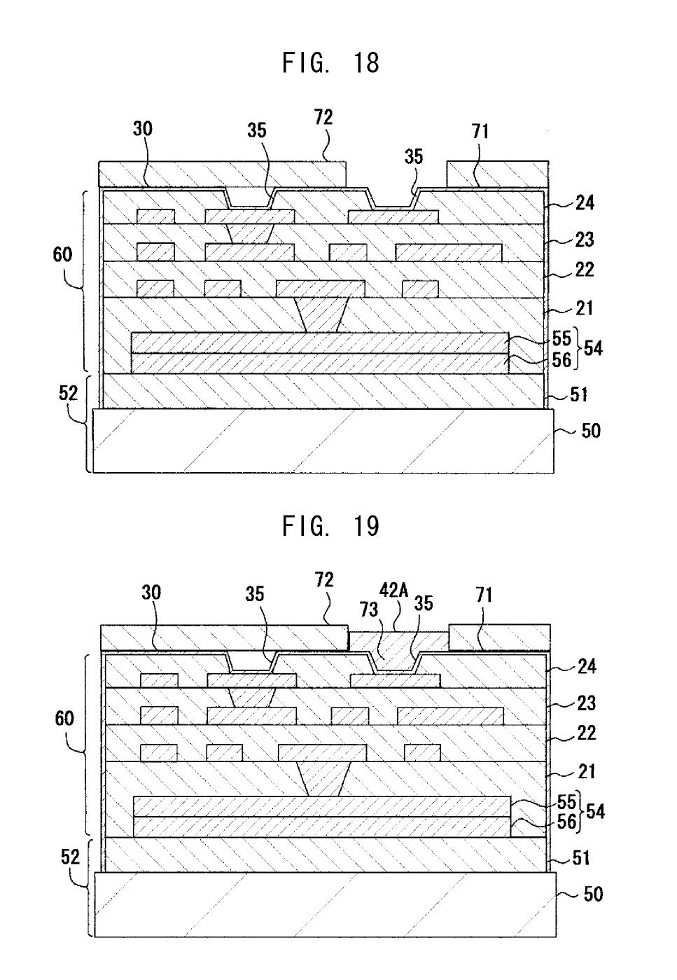

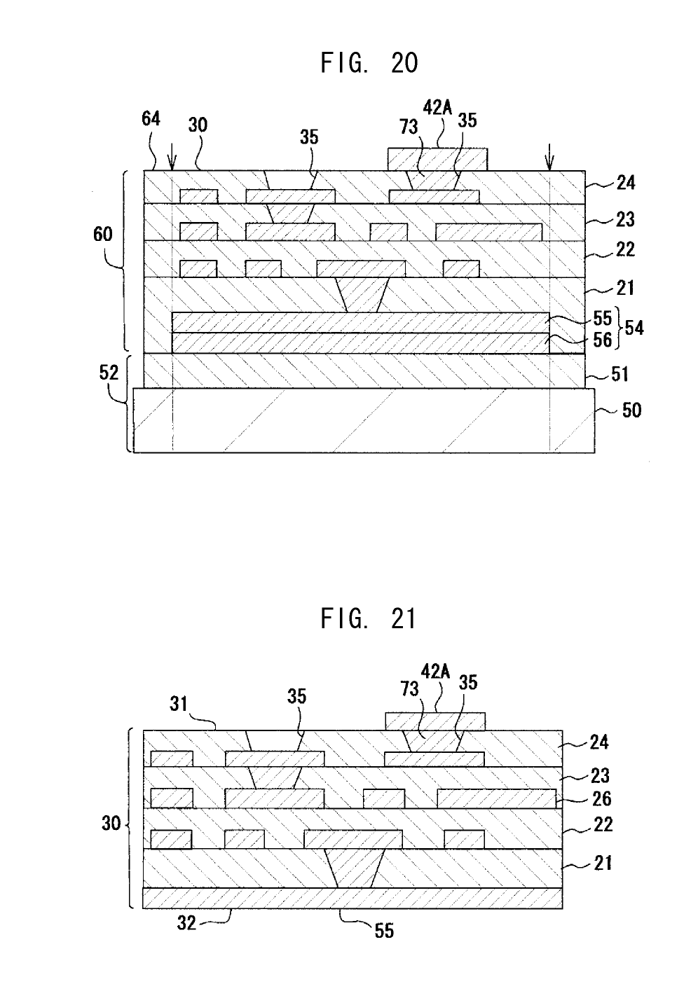

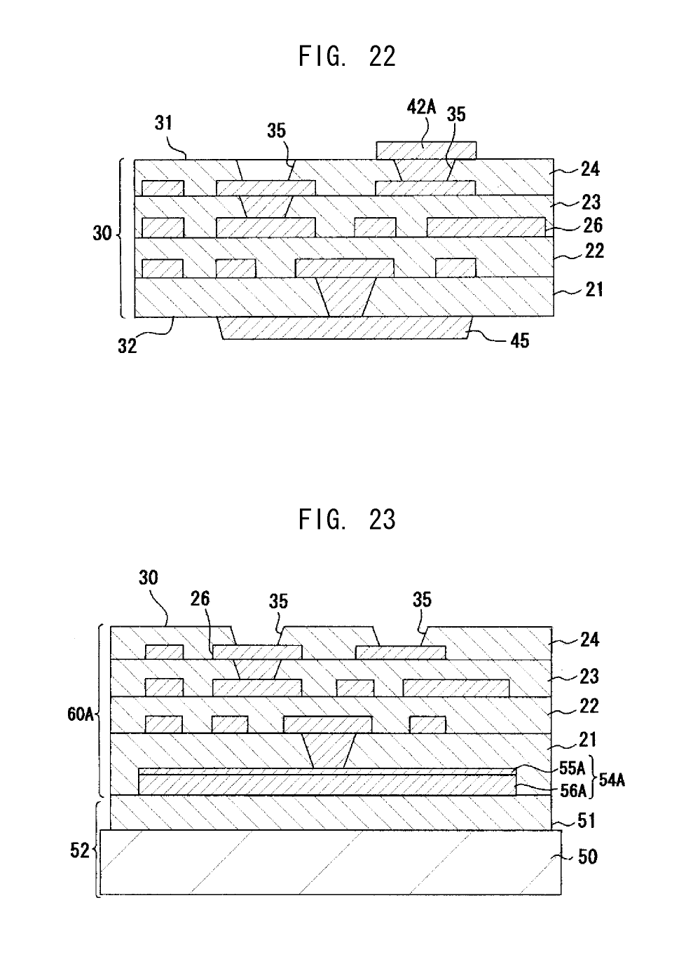

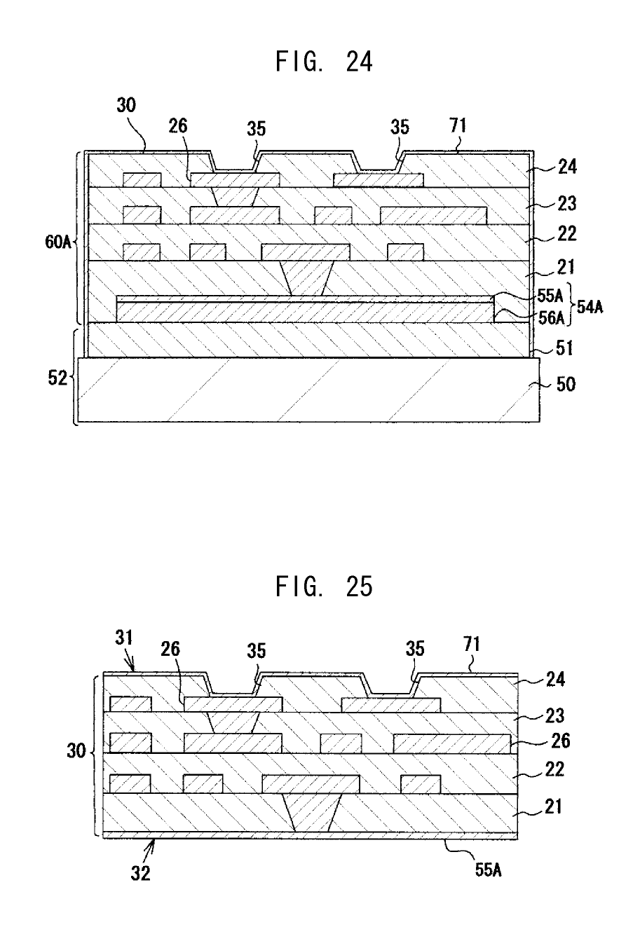

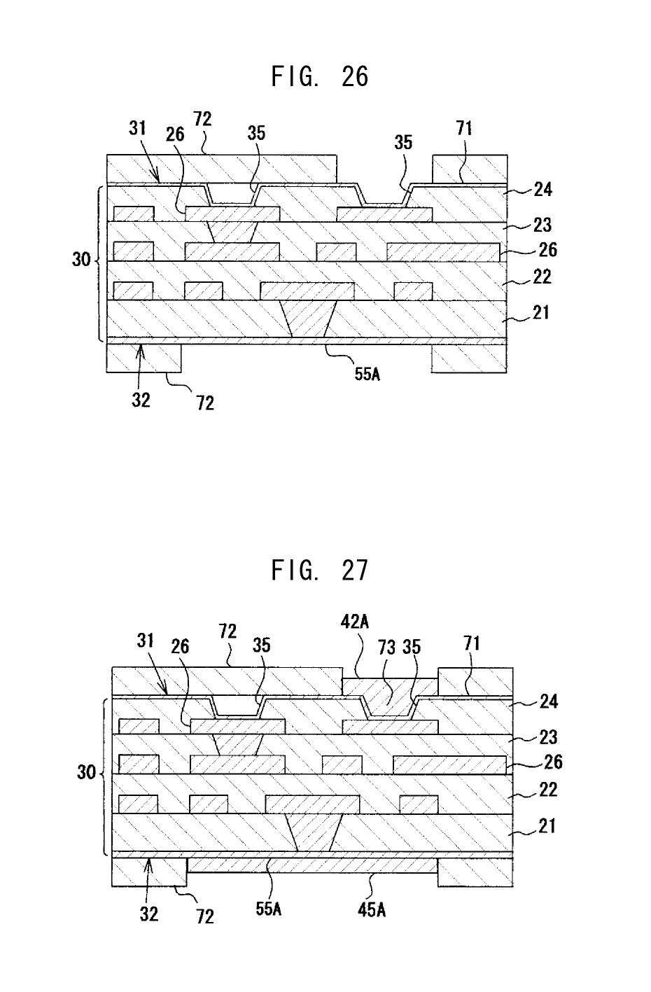

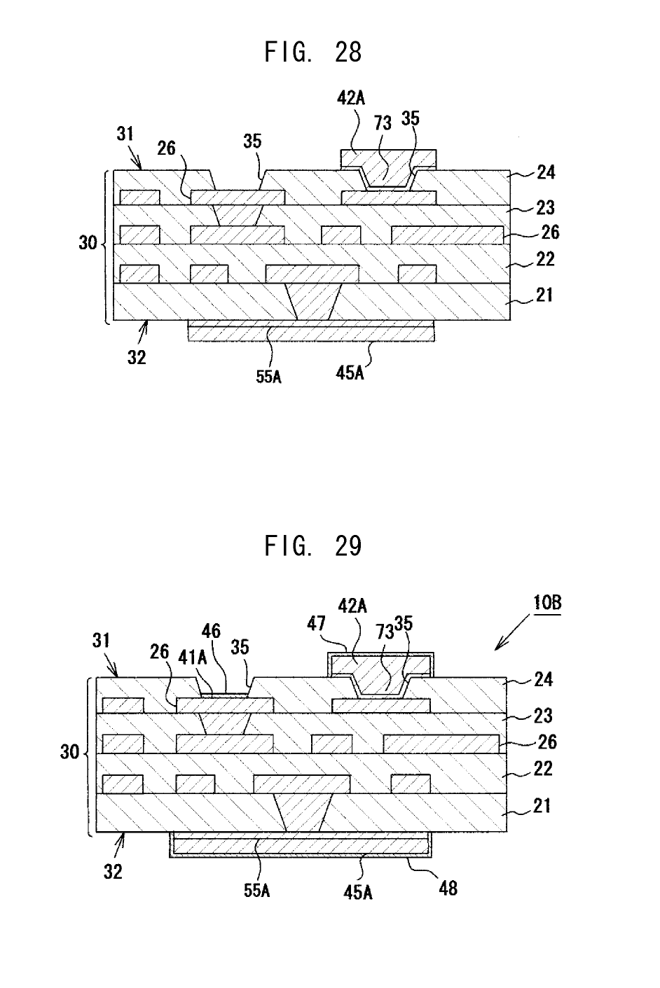

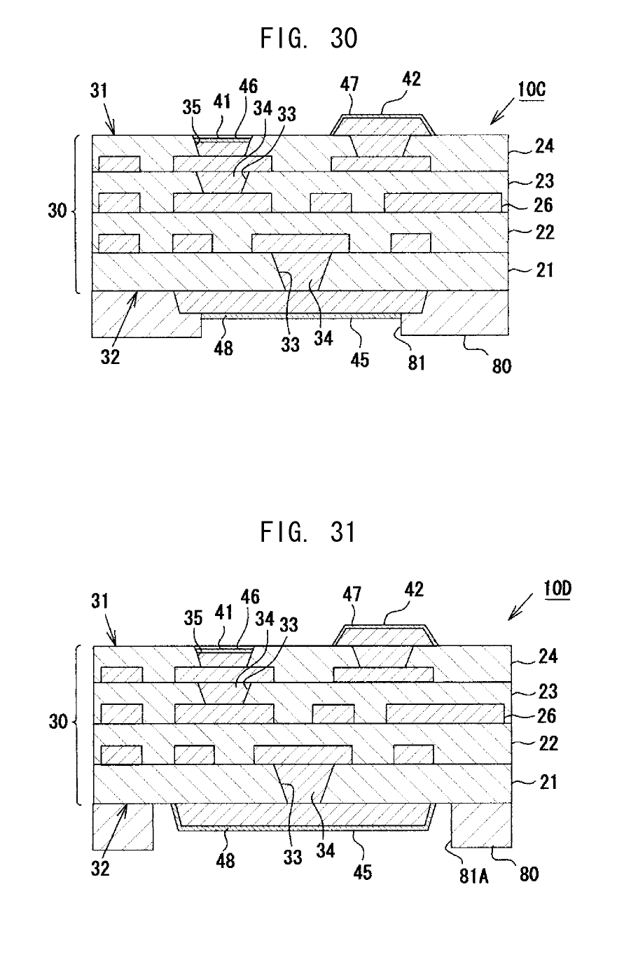

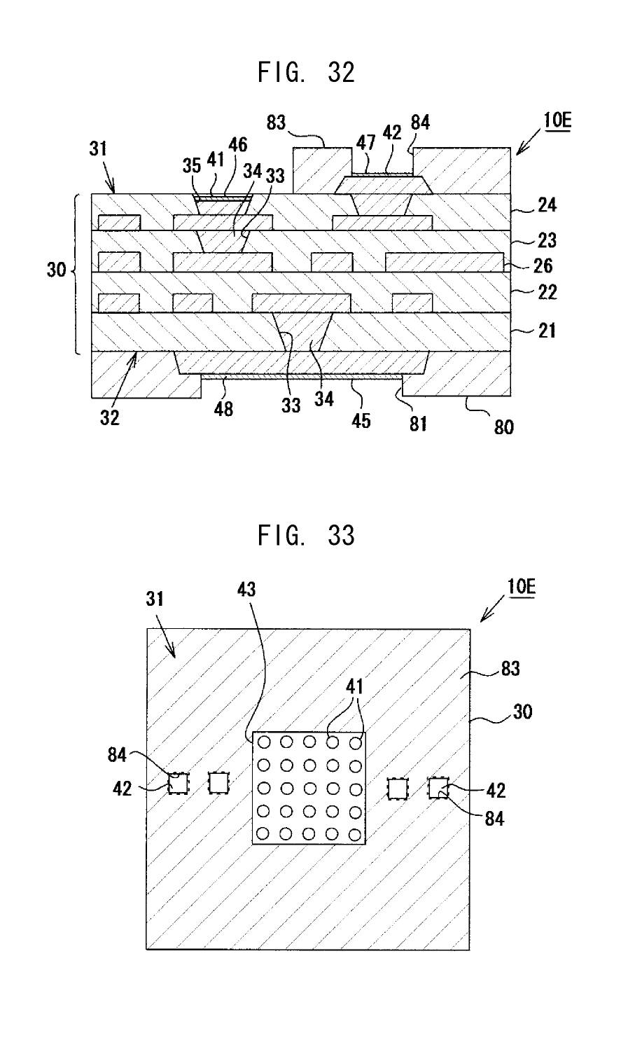

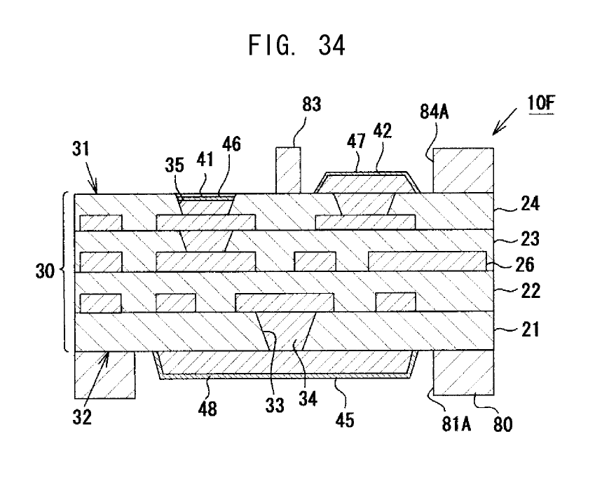

### BRIEF DESCRIPTION OF THE DRAWINGS

[FIG. 1] Sectional view schematically showing the structure of a multilayer wiring substrate according to a first embodiment of the present invention.

[FIG. 2] Plan view schematically showing the structure of the multilayer wiring substrate of FIG. 1.

[FIG. 3] Explanatory view for explaining a method of manufacturing the multilayer wiring substrate of FIG. 1.

[FIG. 4] Explanatory view for explaining the method of manufacturing the multilayer wiring substrate of FIG. 1.

[FIG. 5] Explanatory view for explaining the method of manufacturing the multilayer wiring substrate of FIG. 1.

[FIG. 6] Explanatory view for explaining the method of manufacturing the multilayer wiring substrate of FIG. 1.

[FIG. 7] Explanatory view for explaining the method of manufacturing the multilayer wiring substrate of FIG. 1.

[FIG. 8] Explanatory view for explaining the method of manufacturing the multilayer wiring substrate of FIG. 1.

[FIG. 9] Explanatory view for explaining the method of manufacturing the multilayer wiring substrate of FIG. 1.

[FIG. 10] Explanatory view for explaining the method of manufacturing the multilayer wiring substrate of FIG. 1.

[FIG. 11] Explanatory view for explaining the method of manufacturing the multilayer wiring substrate of FIG. 1.

[FIG. 12] Explanatory view for explaining the method of manufacturing the multilayer wiring substrate of FIG. 1.

[FIG. 13] Explanatory view for explaining the method of manufacturing the multilayer wiring substrate of FIG. 1.

[FIG. 14] Explanatory view for explaining the method of manufacturing the multilayer wiring substrate of FIG. 1.

[FIG. 15] Explanatory view for explaining the method of manufacturing the multilayer wiring substrate of FIG. 1.

[FIG. 16] Sectional view schematically showing the structure of a multilayer wiring substrate according to a second embodiment of the present invention.

[FIG. 17] Explanatory view for explaining a method of manufacturing the multilayer wiring substrate of FIG. 16.

[FIG. 18] Explanatory view for explaining the method of manufacturing the multilayer wiring substrate of FIG. 16.

[FIG. 19] Explanatory view for explaining the method of manufacturing the multilayer wiring substrate of FIG. 16.

[FIG. 20] Explanatory view for explaining the method of manufacturing the multilayer wiring substrate of FIG. 16.

[FIG. 21] Explanatory view for explaining the method of manufacturing the multilayer wiring substrate of FIG. 16.

[FIG. 22] Explanatory view for explaining the method of manufacturing the multilayer wiring substrate of FIG. 16.

[FIG. 23] Explanatory view for explaining a method of manufacturing a modified multilayer wiring substrate of the second embodiment.

[FIG. 24] Explanatory view for explaining the method of manufacturing the modified multilayer wiring substrate of the second embodiment.

[FIG. 25] Explanatory view for explaining the method of manufacturing the modified multilayer wiring substrate of the second embodiment.

[FIG. 26] Explanatory view for explaining the method of manufacturing the modified multilayer wiring substrate of the second embodiment.

[FIG. 27] Explanatory view for explaining the method of manufacturing the modified multilayer wiring substrate of the second embodiment.

[FIG. 28] Explanatory view for explaining the method of manufacturing the modified multilayer wiring substrate of the second embodiment.

[FIG. 29] Explanatory view for explaining the method of manufacturing the modified multilayer wiring substrate of the second embodiment.

[FIG. 30] Sectional view schematically showing the structure of a multilayer wiring substrate according to another embodiment of the present invention.

[FIG. 31] Sectional view schematically showing the structure of a multilayer wiring substrate according to a further embodiment of the present invention.

[FIG. 32] Sectional view schematically showing the structure of a multilayer wiring substrate according to a still further embodiment of the present invention.

[FIG. 33] Sectional view schematically showing the structure of a multilayer wiring substrate according to yet another embodiment of the present invention.

[FIG. 34] Sectional view schematically showing the structure of a multilayer wiring substrate according to another embodiment of the present invention.

### DETAIL DESCRIPTION OF EXEMPLARY EMBODIMENTS OF THE INVENTION

### First Embodiment

A multilayer wiring substrate according to a first embodiment of the present invention will next be described in detail with reference to the drawings. FIG. 1 is an enlarged sectional view schematically showing the structure of the multilayer wiring substrate of the present embodiment. FIG. 2 is a plan view of the multilayer wiring substrate.

As shown in FIG. 1, a multilayer wiring substrate 10 is a coreless wiring substrate having no substrate core and has a multilayer wiring laminate portion 30 (laminate structure) in which four resin insulation layers 21, 22, 23, and 24 made primarily of the same resin insulation material, and conductive layers 26 made of copper are laminated alternately. The resin insulation layers 21 to 24 are formed of a build-up material made primarily of a hardened resin insulation material that is not photocurable; specifically, a hardened thermosetting epoxy resin. In the multilayer wiring substrate 10, a plurality of connection terminals 41 and 42 (first-main-surface-side connection terminals) are disposed on one side (first main surface side) of the wiring laminate portion 30 where a top surface 31 thereof is present.

As shown in FIGS. 1 and 2, in the multilayer wiring substrate 10 of the present embodiment, a plurality of the connection terminals 41 and 42 disposed on the top surface 31 side of the wiring laminate portion 30 are IC-chip connection terminals 41 for connection of an IC chip serving as an article-to-be-connected, and capacitor connection terminals 42 (passive-component connection terminals) for connection of chip capacitors (passive components) serving as articles-to-be-connected. On the top surface 31 of the wiring laminate portion 30, a plurality of the IC-chip connection terminals 41 are arrayed in a chip mounting region 43 provided at a central portion of the multilayer wiring substrate 10. The capacitor connection terminals 42 are greater in area than the IC-chip connection terminals 41 and are disposed externally of the chip mounting region 43.

Meanwhile, on the other side (second main surface side) of the wiring laminate portion 30 where a bottom surface 32 thereof is present, a plurality of connection terminals 45 (motherboard connection terminals serving as second-main-surface-side connection terminals) for LGA (land grid array) and for connection of a motherboard serving as an article-to-be-connected are arrayed. The motherboard connection terminals 45 are greater in area than the IC-chip connection terminals 41 and the capacitor connection terminals 42 on the top surface 31.

Via holes 33 and filled-via conductors 34 are provided in the resin insulation layers 21, 22, 23, and 24. The via conductors 34 are shaped such that a diameter increases along the same direction (in FIG. 1, along the direction from the bottom surface toward the top surface). The via conductors 34 electrically interconnect the conductive layers 26, the IC-chip connection terminals 41, the capacitor connection terminals 42, and the motherboard connection terminals 45.

On the top surface 31 of the wiring laminate portion 30, the fourth resin insulation layer 24 serving as an outermost layer and exposed on the side has openings 35. The IC-chip connection terminals 41 are formed in the openings 35 such that their top surfaces are lower in height than the surface (reference surface) of the resin insulation layer 24. The wall surfaces of the openings 35 are roughened surfaces having fine irregularities. The IC-chip connection terminals 41 are composed primarily of a copper layer, and the copper layer fills the openings 35 while following the roughened surfaces. Further, each IC-chip connection terminal 41 has a structure in which a plating layer 46 of a material other than copper (specifically, a nickel-gold plating layer) covers only the top surface of a portion of the copper layer which portion is the main constituent of the IC-chip connection terminal 41. An IC chip is flip-chip-bonded to the exposed top surfaces of the IC-chip connection terminals 41 via unillustrated solder bumps.

The capacitor connection terminals 42 are composed primarily of a copper layer and formed such that their top surfaces are higher in height than the surface of the resin insulation layer 24. That is, in the multilayer wiring substrate 10 of the present embodiment, the top surfaces of the IC-chip connection terminals 41 and the top surfaces of the capacitor connection terminals 42 differ from each other in height. The top surfaces of the capacitor connection terminals 42 having a relatively large area are higher in height than the top surfaces of the IC-chip connection terminals 41 having a relatively small area. Also, the capacitor connection terminals 42 have a trapezoidal cross section such that the bottom surfaces of the capacitor connection terminals 42 are greater in area than the top surfaces of the capacitor connection terminals 42. Further, each capacitor connection terminal 42 has a structure in which a plating layer 47 of a material other than copper (specifically, a nickel-gold plating layer) covers a top surface and a side surface of a portion of the copper layer which portion is the main constituent of the capacitor connection terminals 42. External terminals of chip capacitors are connected to the capacitor connection terminals 42 via unillustrated solder fillets formed on the top surfaces and the side surfaces of the capacitor connection terminals 42.

The motherboard connection terminals 45 disposed on the bottom surface 32 side of the wiring laminate portion 30 are composed primarily of a copper layer and are formed in such a manner as to be higher in height than the surface of the resin insulation layer 21 serving as an outermost layer and exposed on the bottom surface 32. The motherboard connection terminals 45 have a trapezoidal cross section such that the top surfaces of the motherboard connection terminals 45, the top surfaces being in contact with the resin insulation layer 21, are greater in area than the bottom surfaces of the motherboard connection terminals 45. Further, each motherboard connection terminal 45 has a structure in which a plating layer 48 of a material other than copper (specifically, a nickel-gold plating layer) covers a bottom surface and a side surface of a portion of the copper layer which portion is the main constituent of the motherboard connection terminal 45. The wiring laminate portion 30 is connected to a motherboard via unillustrated solder fillets formed on the bottom surfaces and the side surfaces of the motherboard connection terminals 45.

The thus-configured multilayer wiring substrate 10 is fabricated by, for example, the following procedure.

First, in the build-up step, a support substrate (a glass epoxy substrate or the like) having sufficient strength is prepared. On the support substrate, the resin insulation layers 21 to 24 and the conductive layers 26 are alternately built up, thereby forming the wiring laminate portion 30.

More specifically, as shown in FIG. 3, a sheet-like electrically insulative resin base material made of epoxy resin and serving as a ground resin insulation layer 51 is attached onto a support substrate 50, thereby yielding a base material 52 consisting of the support substrate 50 and the ground resin insulation layer 51. Then, as shown in FIG. 4, a metal laminate sheet 54 is disposed on one side of the base material 52 (specifically, on the upper surface of the ground resin insulation layer 51). Through disposition of the metal laminate sheet 54 on the ground resin insulation layer 51, there is ensured such adhesion that, in the subsequent fabrication process, the metal laminate sheet 54 is not separated from the ground resin insulation layer 51. The metal laminate sheet 54 is configured such that two copper foils 55 and 56 (a pair of metal foils) are separably in close contact with each other. Specifically, the copper foils 55 and 56 are laminated together with metal plating (e.g., chromium plating, nickel plating, titanium plating, or composite plating thereof) intervening therebetween, thereby forming the metal laminate sheet 54.

Subsequently, as shown in FIG. 5, the sheet-like resin insulation layer 21 is disposed on and attached onto the base material 52 in such a manner as to cover the metal laminate sheet 54. At this time, the resin insulation layer 21 comes into close contact with the metal laminate sheet 54 and comes into close contact with the ground resin insulation layer 51 in a region around the metal laminate sheet 54, thereby sealing in the metal laminate sheet 54.

Then, as shown in FIG. 6, the via holes 33 are formed in the resin insulation layer 21 at predetermined positions by means of performing laser beam machining by use of, for example, excimer laser, UV laser, or CO₂ laser. Next, by use of etchant, such as a potassium permanganate solution, a desmear step is performed for removing smears from inside the via holes 33. In the desmear step, in place of treatment by use of etchant, plasma asking by use of, for example, O₂ plasma may be performed.

After the desmear step, electroless copper plating and copper electroplating are performed by a known process, thereby forming the via conductors 34 in the via holes 33. Further, etching is performed by a known process (e.g., semi-additive process), thereby forming the conductive layer 26 in a predetermined pattern on the resin insulation layer 21 (see FIG. 7).

Also, the second to fourth resin insulation layers 22 to 24 and the corresponding conductive layers 26 are formed in layers on the resin insulation layer 21 by processes similar to those used to form the first resin insulation layer 21 and the associated conductive layer 26. Then, laser drilling is performed on the outermost resin insulation layer 24, thereby forming a plurality of the openings 35 (see FIG. 8). Next, the desmear step is performed for removing smears from inside the openings 35 by use of, for example, a potassium permanganate solution or O₂ plasma. When this desmear step is performed, the wall surfaces of the openings 35 are roughened and become roughened surfaces having fine irregularities.

By the above-described build-up step, there is formed a wiring laminate 60 in which the metal laminate sheet 54, the resin insulation layers 21 to 24, and the conductive layers 26 are laminated on the base material 52. As shown in FIG. 8, a portion of the wiring laminate 60 which is located above the metal laminate sheet 54 will become the wiring laminate portion 30 of the multilayer wiring substrate 10.

Then, as shown in FIG. 9, full-surface plating is performed on the outermost resin insulation layer 24 of the wiring laminate 60, thereby forming filled-via conductors 62 made of copper plating in the openings 35 of the resin insulation layer 24 and forming a full-surface plating layer 63 which covers the resin insulation layer 24 (full-panel plating step).

After the full-panel plating step, the wiring laminate 60 is cut by a dicing apparatus (not shown) so as to remove a surrounding portion around the wiring laminate portion 30 (cutting step). At this time, as shown in FIG. 9, cutting progresses along the boundary (indicated by the arrows in FIG. 9) between the wiring laminate portion 30 and a surrounding portion 64 and along the extension of the boundary for further cutting of the base material 52 (the support substrate 50 and the ground resin insulation layer 51) located under the wiring laminate portion 30. As a result of this cutting, a peripheral edge portion of the metal laminate sheet 54 which has been sealed in the resin insulation layer 21 is exposed. That is, as a result of removal of the surrounding portion 64, a bonded portion between the ground resin insulation layer 51 and the resin insulation layer 21 is lost. Consequently, the wiring laminate portion 30 and the base material 52 are connected together merely through the metal laminate sheet 54.

In this condition, as shown in FIG. 10, the wiring laminate portion 30 and the base material 52 are separated from each other at the interface between a pair of the copper foils 55 and 56 of the metal laminate sheet 54, thereby removing the base material 52 from the wiring laminate portion 30 and exposing the copper foil 55 present on the bottom surface of the wiring laminate portion 30 (the resin insulation layer 21) (base-material removing step). Subsequently, the full-surface plating layer 63 and the copper foil 55 of the wiring laminate portion 30 are subjected to patterning by a subtractive process (connection-terminal forming step). Specifically, a dry film is laminated on the top surface 31 (full-surface plating layer 63) of the wiring laminate portion 30 and on the bottom surface 32 (surface of the copper foil 55) of the wiring laminate portion 30. The dry films are subjected to exposure and development, thereby forming etching resist films 66 in predetermined patterns corresponding to the capacitor connection terminals 42 and the motherboard connection terminals 45 (see FIG. 11). In this condition, the full-surface plating layer 63 and the copper foil 55 of the wiring laminate portion 30 are etched for patterning. As a result, the capacitor connection terminals 42 are formed on the resin insulation layer 24, and the motherboard connection terminals 45 are formed on the resin insulation layer 21.

At this time, the top surfaces of the filled-via conductors 62 (copper layer), which fill the openings 35, are exposed, thereby forming the IC-chip connection terminals 41 formed of the filled-via conductors 62. At this time, those regions of the full-surface plating layer 63 and the copper foil 55 which are not covered by the etching resist films 66 are gradually etched away. That is, the full-surface plating layer 63 is gradually etched away from the top surface, which is a side toward the etching resist film 66, and the copper foil 55 is gradually etched away from the bottom surface, which is a side toward the etching resist film 66. Thus, the capacitor connection terminals 42 are formed in such a manner as to have a trapezoidal cross section such that the bottom surfaces of the capacitor connection terminals 42 are greater in area than the top surfaces of the capacitor connection terminals 42; and the motherboard connection terminals 45 are formed in such a manner as to have a trapezoidal cross section such that the top surfaces of the motherboard connection terminals 45 are greater in area than the bottom surfaces of the motherboard connection terminals 45. Then, the etching resist films 66 formed on the capacitor connection terminals 42 and on the motherboard connection terminals 45 are removed by separation (see FIG. 12).

Subsequently, electroless nickel plating and electroless gold plating are sequentially performed on the surfaces (top surfaces and side surfaces) of the capacitor connection terminals 42, the surfaces (bottom surfaces and side surfaces) of the motherboard connection terminals 45, and the surfaces (top surfaces) of the IC-chip connection terminals 41 exposed from the openings 35, thereby forming the nickel-gold plating layers 46, 47, and 48 (plating step). By going through the above-mentioned steps, the multilayer wiring substrate 10 of FIG. 1 is manufactured.

The above-mentioned manufacturing method for the multilayer wiring substrate 10 of the present embodiment may be modified as follows.

As shown in FIG. 13, in the build-up step, the outermost fourth resin insulation layer 24 is formed of a thin-copper-foil-clad build-up material, and the other resin insulation layers 21 to 23 are formed of an ordinary build-up material having no thin copper foil. Accordingly, the top surface of the wiring laminate 60 (surface of the outermost resin insulation layer 24) is covered with a copper foil 68. Subsequently, as shown in FIG. 14, laser drilling is performed so as to form the openings 35, which extend through the copper foil 68, in the resin insulation layer 24 at predetermined positions. Next, a desmear step is performed for removing smears from inside the openings 35.

Then, full-surface plating is performed on the outermost resin insulation layer 24 of the wiring laminate 60, thereby forming the filled-via conductors 62 made of copper plating in the openings 35 of the resin insulation layer 24 and forming the full-surface plating layer 63 which covers the resin insulation layer 24. Subsequently, as described above, the cutting step, the base-material removing step, the connection-terminal forming step, the plating step, etc. are sequentially performed, thereby yielding the multilayer wiring substrate 10 shown in FIG. 1.

Therefore, the present embodiment can yield the following effects.

(1) In the multilayer wiring substrate 10 of the present embodiment, a plurality of the connection terminals 41 and 42 formed on the top surface 31 of the wiring laminate portion 30 differ in top-surface height according to types of articles-to-be-connected. Specifically, a plurality of the connection terminals 41 and 42 are the IC-chip connection terminals 41 for connection of an IC chip, and the capacitor connection terminals 42 for connection of chip capacitors. The IC-chip connection terminals 41 are lower than the surface of the exposed outermost resin insulation layer 24, and the capacitor connection terminals 42 are higher than the surface of the resin insulation layer 24. Through employment of such connection-terminal features, solder bumps for flip-chip bonding of an IC chip can be reliably formed on the IC-chip connection terminals 41, so that the IC chip can be reliably connected. Also, solder fillets for connection of chip capacitors can be reliably formed on the capacitor connection terminals 42, so that the chip capacitors can be reliably connected.

(2) In the multilayer wiring substrate 10 of the present embodiment, the openings 35 are formed in the resin insulation layer 24 exposed on the top surface 31 of the wiring laminate portion 30, and the IC-chip connection terminals 41 are formed in the openings 35 such that the top surfaces of the IC-chip connection terminals 41 are lower in height than the surface of the resin insulation layer 24. Through employment of this configuration, depressions are formed at the positions of the IC-chip connection terminals 41. Thus, solder balls can be readily positioned on the IC-chip connection terminals 41 within the openings 35. Therefore, solder bumps can be more reliably formed on the IC-chip connection terminals 41.

(3) In the multilayer wiring substrate 10 of the present embodiment, the wall surfaces of the openings 35 formed in the outermost resin insulation layer 24 are roughened surfaces, and the filled-via conductors 62 which partially constitute the IC-chip connection terminals 41 fill the openings 35 while following the roughened surfaces. Through such formation of the IC-chip connection terminals 41, adhesion between the IC-chip connection terminals 41 and the resin insulation layer 24 can be enhanced. As a result, separation of the IC-chip connection terminals 41 or a like problem can be reliably prevented, whereby the reliability of the multilayer wiring substrate 10 can be enhanced.

(4) In the multilayer wiring substrate 10 of the present embodiment, since the capacitor connection terminals 42 have a structure in which the plating layer 47 covers the top and side surfaces of the capacitor connection terminals 42, relatively large solder fillets can be reliably formed on the top and side surfaces. Also, since the IC-chip connection terminals 41 have a structure in which the plating layer 46 covers the top surfaces of the IC-chip connection terminals 41, solder bumps can be reliably formed on the top surfaces. The interval between the capacitor connection terminals 42 is greater than that between the IC-chip connection terminals 41, and the capacitor connection terminals 42 have a relatively large size; thus, by means of the solder fillets formed on the top surfaces and the side surfaces of the capacitor connection terminals 42, chip capacitors can be reliably soldered to the capacitor connection terminals 42 with a sufficient strength. Meanwhile, since the interval between the IC-chip connection terminals 41 is small, if solder bumps bulge from the side surfaces of the IC-chip connection terminals 41, a problem of a short circuit between the IC-chip connection terminals 41 will arise. However, in the present invention, since solder bumps are formed only on the top surfaces of the IC-chip connection terminals 41, the solder bumps do not expand laterally, so that a short circuit between the IC-chip connection terminals 41 can be avoided.

(5) In the multilayer wiring substrate 10 of the present embodiment, the capacitor connection terminals 42 have a trapezoidal cross section such that the bottom surfaces of the capacitor connection terminals 42, the bottom surfaces being in contact with the resin insulation layer 24, are greater in area than the top surfaces of the capacitor connection terminals 42, the top surfaces being opposite the bottom surface. Thus, the contact area between the resin insulation layer 24 and the bottom surfaces of the capacitor connection terminals 42 increases, whereby the strength of the capacitor connection terminals 42 can be sufficiently ensured. Also, the motherboard connection terminals 45 have a trapezoidal cross section such that the top surfaces of the motherboard connection terminals 45, the top surfaces being in contact with the resin insulation layer 21, are greater in area than the bottom surfaces of the motherboard connection terminals 45, the bottom surfaces being opposite the top surfaces. Thus, the contact area between the resin insulation layer 21 and the top surfaces of the motherboard connection terminals 45 increases, whereby the strength of the motherboard connection terminals 45 can be sufficiently ensured.

(6) In the multilayer wiring substrate 10 of the present embodiment, the capacitor connection terminals 42 having a relatively large area are higher in top-surface height than the IC-chip connection terminals 41 having a relatively small area. Through employment of this height feature, chip capacitors having a large connection area and an IC-chip having a small connection area can be reliably connected to the connection terminals 41 and 42, respectively, of different heights.

(7) In the multilayer wiring substrate 10 of the present embodiment, a plurality of the resin insulation layers 21 to 24 are formed of the same build-up material made primarily of a hardened resin insulation material that is not photocurable. That is, the outermost resin insulation layer 24 is formed of the same build-up material having excellent electrical insulation performance as that used to form the inner resin insulation layers 22 and 23. Thus, the interval between the IC-chip connection terminals 41 and that between the capacitor connection terminals 42 can be narrowed, so that the multilayer wiring substrate 10 can be further integrated. Also, in the multilayer wiring substrate 10, since solder resist film is not formed on the outermost layers, there can be avoided warpage of the multilayer wiring substrate 10 which could otherwise result from the difference in thermal expansion coefficient between the resin insulation layers 21 to 24 and the solder resist film.

(8) In the method of manufacturing the multilayer wiring substrate 10 of the present embodiment, the wiring laminate portion 30 after the base-material removing step is in a condition in which the full-surface plating layer 63 is formed on the top surface 31, and the copper foil 55 is formed on the bottom surface 32. In this case, similar to the case of manufacture of an ordinary wiring substrate, the top surface 31 and the bottom surface 32 can be simultaneously subjected to patterning by a subtractive process for simultaneous formation of the connection terminals 42 and 45 on the top and bottom surfaces 31 and 32, respectively. Therefore, conventional manufacturing equipment for patterning by a subtractive process can be used, so that the cost of manufacturing the multilayer wiring substrate 10 can be reduced.

(9) In the method of manufacturing the multilayer wiring substrate 10 of the present embodiment, in the case of use of a thin-copper-foil-clad build-up material having a thin copper foil formed thereon, when, after formation of the openings 35 by laser drilling, a desmear step is performed, the surface of the outermost resin insulation layer 24 of the wiring laminate portion 30 is not roughened by the desmear step, since the surface is covered with the copper foil 68. Also, in this case, the surface roughness of the resin insulation layer 24 is determined through transfer of the roughness of a contact surface of the copper foil 68 to the surface of the resin insulation layer 24. Thus, the surface of the outermost resin insulation layer 24 of the wiring laminate portion 30 can have a uniform surface roughness.

### Second Embodiment

Next, a second embodiment of the present invention will be described with reference to the drawings. As shown in FIG. 16, a multilayer wiring substrate 10A of the present embodiment differs from the above-described multilayer wiring substrate 10 of the first embodiment such that IC-chip connection terminals 41A and capacitor connection terminals 42A differ from their counterparts in shape and a manufacturing method therefor. The following description focuses on points of difference from the first embodiment.

As shown in FIG. 16, in the multilayer wiring substrate 10A, filled-via conductors are not formed in the openings 35 of the outermost resin insulation layer 24, and the height of the top surfaces of the IC-chip connection terminals 41A formed in the openings 35 is substantially identical to that of an underlying pattern layer (the conductive layer 26 formed on the resin insulation layer 23). Further, the plating layer 46 is formed on the top surfaces of the IC-chip connection terminals 41A exposed from the openings 35. Also, the capacitor connection terminals 42A are formed such that the area of a top surface and the area of a bottom surface are substantially equal to each other.

The multilayer wiring substrate 10A of the present embodiment is fabricated by the following procedure.

First, similar to the first embodiment, a build-up step is performed for forming the wiring laminate 60 as shown in FIG. 8. Subsequently, as shown in FIG. 17, electroless copper plating is performed, thereby forming a full-surface plating layer 71 which covers the resin insulation layers 21 to 24 and the interiors of the openings 35 of the resin insulation layer 24 (full-surface plating step).

Then, as shown in FIG. 18, a dry film is laminated on the top surface of the wiring laminate 60. The dry film is subjected to exposure and development, thereby forming a plating resist film 72 in a pattern corresponding to the capacitor connection terminals 42A. As shown in FIG. 19, through selective pattern plating in a condition in which the plating resist film 72 is formed, filled-via conductors 73 are formed in a part of a plurality of the openings 35, and the capacitor connection terminals 42A are formed on the filled-via conductors 73 (filled-via-conductor forming step).

After the filled-via-conductor forming step, as shown in FIG. 20, through patterning by a semi-additive process, the full-surface plating layer 71 is removed while the filled-via conductors 73 and the capacitor connection terminals 42A are left intact (full-surface-plating-layer removing step).

After the full-surface-plating-layer removing step, the wiring laminate 60 is cut by a dicing apparatus (not shown) so as to remove a surrounding portion around the wiring laminate portion 30 (cutting step). At this time, as shown in FIG. 20, cutting progresses along the boundary (indicated by the arrows in FIG. 20) between the wiring laminate portion 30 and the surrounding portion 64 and along the extension of the boundary for further cutting of the base material 52 (the support substrate 50 and the ground resin insulation layer 51) located under the wiring laminate portion 30. As a result of this cutting, a peripheral edge portion of the metal laminate sheet 54 which has been sealed in the resin insulation layer 21 is exposed.

In this condition, as shown in FIG. 21, the wiring laminate portion 30 and the base material 52 are separated from each other at the interface between a pair of the copper foils 55 and 56 of the metal laminate sheet 54, thereby removing the base material 52 from the wiring laminate portion 30 and exposing the copper foil 55 present on the bottom surface 32 of the wiring laminate portion 30 (the resin insulation layer 21) (base-material removing step).

After the base-material removing step, the copper foil 55 of the wiring laminate portion 30 is subjected to patterning by a subtractive process, thereby forming the motherboard connection terminals 45 (connection-terminal forming step). Specifically, a dry film is laminated on the top surface 31 and the bottom surface 32 of the wiring laminate portion 30. The dry films are subjected to exposure and development. By this procedure, an etching resist film is formed on the entire top surface 31 of the wiring laminate portion 30, and an etching resist film in a predetermined pattern corresponding to the motherboard connection terminals 45 is formed on the bottom surface 32. In this condition, the copper foil 55 on the bottom surface 32 of the wiring laminate portion 30 is etched for patterning, thereby removing unnecessary portions of the copper foil 55 and thus forming the motherboard connection terminals 45 on the resin insulation layer 21. After the connection-terminal forming step, the etching resist films formed on the top surface 31 and the bottom surface 32 of the wiring laminate portion 30 are removed by separation (see FIG. 22).

Subsequently, electroless nickel plating and electroless gold plating are sequentially performed on the surfaces (top surfaces and side surfaces) of the capacitor connection terminals 42A, the surfaces (bottom surfaces and side surfaces) of the motherboard connection terminals 45, and the surfaces (top surfaces) of the IC-chip connection terminals 41A exposed from the openings 35, thereby forming the nickel-gold plating layers 46, 47, and 48 (plating step). By going through the above-mentioned steps, the multilayer wiring substrate 10A of FIG. 16 is manufactured.

Therefore, the multilayer wiring substrate 10A of the present embodiment can yield effects similar to those which the first embodiment described above does. Also, according to the method of manufacturing the multilayer wiring substrate 10A of the present embodiment, a plurality of the openings 35 can be formed in the outermost resin insulation layer 24 exposed at the top surface 31 of the wiring laminate portion 30 in such a manner as to have a uniform depth. In this case, fine solder balls can be readily positioned on the IC-chip connection terminals 41A within the openings 35, and solder bumps can be more reliably formed on the IC-chip connection terminals 41A.

The embodiments of the present invention may be modified as follows.

In manufacture of the multilayer wiring substrate 10A of the second embodiment, the capacitor connection terminals 42A on the top surface 31 are formed through patterning by a semi-additive process, and the motherboard connection terminals 45 on the bottom surface 32 are formed through pattering by a subtractive process. However, the present invention is not limited thereto. For example, the motherboard connection terminals 45 on the bottom surface 32 may be formed through patterning by a semi-additive process. A specific manufacturing method is described below.

First, a built-up step is performed, thereby yielding a wiring laminate 60A as shown in FIG. 23. The wiring laminate 60A differs from the wiring laminate 60 of FIG. 8 in that a metal laminate sheet 54A consists of copper foils 55A and 56A of different thicknesses. In the metal laminate sheet 54A, the copper foil 55A disposed on the side toward the top surface is thinner than the copper foil 56A disposed on the side toward the bottom surface (on the side toward the base material 52). The thickness of the copper foil 55A is about 3 μm to 5 μm.

After the build-up step, as shown in FIG. 24, electroless copper plating is performed, thereby forming the full-surface plating layer 71 which covers the resin insulation layers 21 to 24 and the interiors of the openings 35 of the resin insulation layer 24 (full-surface plating step).

Subsequently, a cutting step is performed; specifically, the wiring laminate 60A is cut by a dicing apparatus (not shown) so as to remove a surrounding portion around the wiring laminate portion 30. Then, a base-material removing step is performed; specifically, the wiring laminate portion 30 and the base material 52 are separated from each other at the interface between a pair of the copper foils 55A and 56A of the metal laminate sheet 54A, thereby removing the base material 52 from the wiring laminate portion 30 and exposing the copper foil 55A present on the bottom surface 32 of the wiring laminate portion 30 (resin insulation layer 21), as shown in FIG. 25.

A dry film is laminated on the top surface 31 and the bottom surface 32 of the wiring laminate portion 30. The dry films are subjected to exposure and development. By this procedure, the plating resist films 72 are formed in patterns corresponding to the capacitor connection terminals 42A and the motherboard connection terminals 45A (see FIG. 26).

Subsequently, as shown in FIG. 27, selective pattern plating is performed in a condition in which the plating resist films 72 are formed. By this procedure, at the top surface 31 of the wiring laminate portion 30, the filled-via conductors 73 are formed in a part of a plurality of the openings 35, and the capacitor connection terminals 42A are formed on the filled-via conductors 73. Also, at the bottom surface 32 of the wiring laminate portion 30, the motherboard connection terminals 45A are formed on the copper foil 55A.

Then, as shown in FIG. 28, patterning is performed by a semi-additive process. By means of this patterning, at the top surface 31, the full-surface plating layer 71 is removed while the capacitor connection terminals 42A and the filled-via conductors 73 are left intact. Also, at the bottom surface 32, the copper foil 55A is removed while the motherboard connection terminals 45A are left intact. Subsequently, electroless nickel plating and electroless gold plating are sequentially performed on the surfaces of the IC-chip connection terminals 41A, the surfaces of the capacitor connection terminals 42A, and the surfaces of the motherboard connection terminals 45A, thereby forming the nickel-gold plating layers 46, 47, and 48 (see FIG. 29). By going through the above-mentioned steps, a multilayer wiring substrate 10B of FIG. 29 is manufactured. The multilayer wiring substrate 10B can also yield effects similar to those which the second embodiment described above does.

In the multilayer wiring substrates 10, 10A, and 10B, a plurality of the resin insulation layers 21 to 24, which partially constitute the wiring laminate portion 30, are formed of a build-up material made primarily of a hardened resin insulation material that is not photocurable. The multilayer wiring substrates 10, 10A, and 10B may be provided with solder resist film made primarily of a hardened photocurable resin insulation material. FIGS. 30 to 34 show multilayer wiring substrates 10C to 10F provided with the solder resist film.

In the multilayer wiring substrate 10C of FIG. 30, a solder resist film 80 is provided only on the bottom surface 32 of the wiring laminate portion 30, and the solder resist film 80 has openings 81 through which the motherboard connection terminals 45 are exposed. In the multilayer wiring substrate 10C, the openings 81 of the solder resist film 80 are smaller than the motherboard connection terminals 45, and the solder resist film 80 covers peripheral portions of the surfaces of the motherboard connection terminals 45. Also, in the multilayer wiring substrate 10D of FIG. 31, the solder resist film 80 is provided only on the bottom surface 32 of the wiring laminate portion 30, and the solder resist film 80 has openings 81A through which the motherboard connection terminals 45 are exposed. In the multilayer wiring substrate 10D, the openings 81A of the solder resist film 80 are greater than the motherboard connection terminals 45, and the entire bottom and side surfaces of the motherboard connection terminals 45 are exposed. As in the case of the multilayer wiring substrates 10C and 10D, through provision of the solder resist film 80 on the bottom surface 32 of the wiring laminate portion 30, the motherboard connection terminals 45 can be protected, thereby preventing potential damage to the motherboard connection terminals 45 in the course of conveyance or a like operation of the substrates.

In the multilayer wiring substrate 10E of FIG. 32, in addition to the solder resist film 80 on the bottom surface 32 of the wiring laminate portion 30, a solder resist film 83 is provided on the top surface 31; and the solder resist film 83 has openings 84 through which the capacitor connection terminals 42 are exposed. The solder resist film 83 is provided in a region other than the chip mounting region 43 (a region located externally of the chip mounting region 43) on the upper surface 31 of the wiring laminate portion 30 (see FIG. 33). In the multilayer wiring substrate 10E, the openings 84 of the solder resist film 83 are smaller than the capacitor connection terminals 42, and the solder resist film 83 covers peripheral portions of the surfaces of the capacitor connection terminals 42.

Also, in the multilayer wiring substrate 10F of FIG. 34, in addition to the solder resist film 80 on the bottom surface 32 of the wiring laminate portion 30, solder resist film 83 is provided on the top surface 31; and the solder resist film 83 has openings 84A through which the capacitor connection terminals 42 are exposed. In the multilayer wiring substrate 10F, the openings 84A of the solder resist film 83 are greater than the capacitor connection terminals 42, and the entire top and side surfaces of the capacitor connection terminals 42 are exposed. As in the case of the multilayer wiring substrates 10E and 10F, through provision of the solder resist film 83, the capacitor connection terminals 42 can be protected. Also, through provision of the solder resist film 83, a level difference is formed between the chip mounting region 43 and its surrounding region on the top surface 31 of the wiring laminate portion 30. Therefore, there can be avoided a problem that flux and an underfill material charged into the chip mounting region 43 protrude to the exterior of the chip mounting region.

Further, in the multilayer wiring substrates 10E and 10F, the solder resist film 83 may be provided in the chip mounting region 43. In this case, openings are formed in the solder resist film 83 of the chip mounting region 43 for exposing the IC-chip connection terminals 41 therethrough. The openings through which the IC-chip connection terminals 41 are exposed may be smaller or greater than the IC-chip connection terminals 41 according to the type of an IC chip to be mounted.

The wiring laminate portions 30 of the multilayer wiring substrates 10C to 10F have the same configuration as that of the first embodiment. The formation of the solder resist films 80 and 83 as in the case of the multilayer wiring substrates 10C to 10F may cause warpage of the substrate due to the difference in thermal expansion coefficient between the solder resist films 80 and 83 and the resin insulation layers 21 to 24, which partially constitute the wiring laminate portion 30. In order to prevent such warpage, the area of the solder resist films formed on the top surface 31 and the bottom surface 32 of the wiring laminate portion 30 may be adjusted, and dummy electrodes may be provided additionally.

In the embodiments described above, a plurality of the conductive layers 26 formed in a plurality of the resin insulation layers 21 to 24 are interconnected by means of the via conductors 34 shaped such that a diameter increases along a direction from the bottom surface 32 to the top surface 31. However, the present invention is not limited thereto. The via conductors 34 formed in a plurality of the resin insulation layers 21 to 24 may be shaped such that a diameter increases along the same direction; for example, a plurality of the conductive layers 26 may be interconnected by means of via conductors shaped such that a diameter increases along a direction from the top surface 31 to the bottom surface 32.

In the embodiments described above, the plating layers 46, 47, and 48 which cover the connection terminals 41, 42, and 45, respectively, are nickel-gold plating layers. However, the present invention is not limited thereto. The plating layers 46, 47, and 48 may be of a material other than copper; for example, a nickel-palladium-gold plating layer or the like may be employed.

In the embodiments described above, the IC-chip connection terminals 41 are formed in the openings 35 such that their top surfaces are lower in height than the surface (reference surface) of the resin insulating layer 24. However, The IC-chip connection terminals 41 may be formed in the openings 35 such that their top surfaces are higher in height than the surface (reference surface). Specifically, the IC-chip connection terminals 41 may project (protrude) from the reference surface. A specific manufacturing method is described below.

As shown in FIG. 11, the dry films are subjected to exposure and development, thereby forming etching resist films 66 in predetermined patterns corresponding to the capacitor connection terminals 42. At this time, etching resist films 66 are also formed in predetermined patterns corresponding to the IC-chip connection terminals 41. In this condition, as described above, the connection-terminal forming step is performed. As a result, the capacitor connection terminals 42 and the IC-chip connection terminals 41 projecting (protruding) from the reference surface are formed on the resin insulation layer 24. Subsequently, the plating step is performed, thereby forming the nickel-gold plating layers on the surface of the IC-chip connection terminals 41 projecting (protruding) from the reference surface

Next, technical ideas that the embodiments described above implement are enumerated below.

(1) A multilayer wiring substrate has a laminate structure in which a plurality of resin insulation layers made of the same insulation material, and a plurality of conductive layers are laminated alternately in multilayer arrangement. A plurality of first-main-surface-side connection terminals are disposed on one side of the laminate structure where a first main surface thereof is present. A plurality of second-main-surface-side connection terminals are disposed on the other side of the laminate structure where a second main surface thereof is present. Via conductors whose diameters increase along the same direction are formed in the plurality of resin insulation layers. The multilayer wiring substrate is characterized in the following: at least two types of the second-main-surface-side connection terminals for connection of different articles-to-be-connected are present on the second main surface side; and top surfaces of the second-main-surface-side connection terminals differ in height according to types of the articles-to-be-connected.

(2) The multilayer wiring substrate described above in (1) is characterized by the following: not only the motherboard connection terminals for connection of a motherboard serving as the article-to-be-connected but also IC-chip connection terminals for connection of an IC chip, or passive-component connection terminals for connection of a passive component are present on the second main surface side.

(3) A method of manufacturing a multilayer wiring substrate manufactures a multilayer wiring substrate having a laminate structure in which a plurality of resin insulation layers made of the same insulation material, and a plurality of conductive layers are laminated alternately in multilayer arrangement, a plurality of first-main-surface-side connection terminals being disposed on one side of the laminate structure where a first main surface thereof is present, a plurality of second-main-surface-side connection terminals being disposed on the other side of the laminate structure where a second main surface thereof is present, via conductors whose diameters increase along the same direction being formed in the plurality of resin insulation layers. The method of manufacturing the multilayer wiring substrate includes a build-up step of alternately laminating a plurality of resin insulation layers made of the same insulation material, and a plurality of conductive layers in multilayer arrangement on a side of a base material where a pair of metal foils are laminated in a mutually separable condition, thereby forming a laminate structure; a full-panel plating step of performing full-panel plating on an outermost resin insulation layer of the laminate structure, thereby forming filled-via conductors in the resin insulation layer and forming a full-surface plating layer which covers the entire surface of the resin insulation layer; a base-material removing step of, after the full-panel plating step, separating the pair of metal foils from each other, thereby removing the base material and exposing the metal foil; and a connection-terminal forming step of, after the base-material removing step, patterning the full-surface plating layer and the metal foil on the laminate structure by a subtractive process, thereby forming the first-main-surface-side connection terminals and the second-main-surface-side connection terminals.

(4) The method of manufacturing a multilayer wiring substrate described above in (3) is characterized by the following: in the build-up step, in formation of the outermost resin insulation layer of the laminate structure, there is used a thin-copper-foil-clad build-up material having a thin copper foil formed on its surface, and made primarily of a resin insulation material that is not photocurable, and laser drilling is performed on the laminated thin-copper-foil-clad build-up material, thereby forming openings for forming filled-via conductors therein; and, after the build-up step and before the full-panel plating step, a desmear step is performed for removing smears from inside the openings.

(5) A method of manufacturing a multilayer wiring substrate manufactures a multilayer wiring substrate having a laminate structure in which a plurality of resin insulation layers made of the same insulation material, and a plurality of conductive layers are laminated alternately in multilayer arrangement, a plurality of first-main-surface-side connection terminals being disposed on one side of the laminate structure where a first main surface thereof is present, a plurality of second-main-surface-side connection terminals being disposed on the other side of the laminate structure where a second main surface thereof is present, via conductors whose diameters increase along the same direction being formed in the plurality of resin insulation layers. The method of manufacturing the multilayer wiring substrate includes a build-up step of alternately laminating a plurality of resin insulation layers made of the same insulation material, and a plurality of conductive layers in multilayer arrangement on a side of a base material where a pair of metal foils are laminated in a mutually separable condition, thereby forming a laminate structure, and performing laser drilling on the outermost resin insulation layer of the laminate structure, thereby forming a plurality of openings; a full-surface plating step of forming, by electroless plating, a full-surface plating layer which covers the outermost resin insulation layer and the interiors of the plurality of openings; a filled-via-conductor forming step of forming filled-via conductors in a part of the plurality of openings through selective pattern plating in a condition in which a plating resist film is formed on the first main surface; a full-surface-plating-layer removing step of, after the filled-via-conductor forming step, removing the full-surface plating layer while leaving the filled-via conductors intact, through patterning by a semi-additive process; a base-material removing step of, after the full-surface-plating-layer removing step, separating the pair of metal foils from each other, thereby removing the base material and exposing the metal foil; and a connection-terminal forming step of, after the base-material removing step, patterning the metal foil on the laminate structure by a subtractive process, thereby forming the second-main-surface-side connection terminals.

### DESCRIPTION OF REFERENCE NUMERALS

10, 10A to 10F: multilayer wiring substrate
21 to 24: resin insulation layer
26: conductive layer
30: wiring laminate portion serving as laminate structure
31: top surface serving as first main surface
32: bottom surface serving as second main surface
33: via conductor
35: opening
41, 41A: IC-chip connection terminal
42, 42A: capacitor connection terminal serving as passive-component connection terminal
45, 45A: motherboard connection terminal serving as second-main-surface-side connection terminal
46, 47: plating layer
52: base material
55: copper foil serving as metal foil
62: filled-via conductor serving as copper layer
80: solder resist film

What is claimed is:

1. A multilayer wiring substrate having a laminate structure in which a plurality of resin insulation layers made primarily of the same resin insulation material and a plurality of conductive layers are laminated alternately in multilayer arrangement, a plurality of first-main-surface-side connection terminals being disposed on one side of the laminate structure where a first main surface thereof is present, a plurality of second-main-surface-side connection terminals being disposed on an other side of the laminate structure where a second main surface thereof is present, the plurality of conductive layers being formed in the plurality of resin insulation layers and interconnected by means of via conductors whose diameters increase toward the first main surface or the second main surface,
the plurality of first-main-surface-side connection terminals comprising at least two types of terminals for connection of different articles-to-be-connected, and
wherein top surfaces of the plurality of first-main-surface-side connection terminals differ in height according to types of the articles-to-be-connected.

2. The multilayer wiring substrate according to claim 1,
wherein one type of the plurality of first-main-surface-side connection terminals are IC-chip connection terminals for connection of an IC chip, and an other type of the plurality of first-main-surface-side connection terminals are passive-component connection terminals for connection of a passive component, the passive-component connection terminals being greater in area than the IC-chip connection terminals, and
when a surface of a resin insulation layer serving as an outermost layer and exposed as the first main surface is defined as a reference surface, top surfaces of the passive-component connection terminals protrude from the reference surface, and top surfaces of the IC-chip connection terminals are flush with or recessed from the reference surface.

3. The multilayer wiring substrate according to claim 2, wherein the resin insulation layer serving as an outermost layer and exposed as the first main surface has openings, and the IC-chip connection terminals are formed in the openings such that the top surfaces of the IC-chip connection terminals are recessed from the reference surface.

4. The multilayer wiring substrate according to claim 3, wherein: walls defining the openings have roughened wall surfaces; the IC-chip connection terminals are composed primarily of a copper layer; and the copper layer fills the openings while following the roughened wall surfaces.

5. The multilayer wiring substrate according to claim 1, wherein one type of the plurality of first-main-surface-side connection terminals are IC-chip connection terminals for connection of an IC chip, and an other type of the plurality of first-main-surface-side connection terminals are passive-component connection terminals for connection of a passive component, the passive-component connection terminals being greater in area than the IC-chip connection terminals, and
wherein each passive-component connection terminal has a structure in which a plating layer of a material other than copper covers a top surface and a side surface of a portion of a copper layer which portion is a main constituent of the passive-component connection terminals, and each IC-chip connection terminal has a structure in which a plating layer of a material other than copper covers only a top surface of a portion of the copper layer which portion is a main constituent of the IC-chip connection terminals.

6. The multilayer wiring substrate according to claim 2, wherein each passive-component connection terminal has a trapezoidal cross section such that a bottom surface of each passive-component connection terminal is greater in area than a top surface of each passive-component connection terminal.

7. The multilayer wiring substrate according to claim 1,
wherein one type of the plurality of first-main-surface-side connection terminals are greater in area than an other type of the plurality of first-main-surface-side connection terminals, and
wherein the one type of the plurality of first-main-surface-side connection terminals having a greater area are higher in top-surface height than the other type of first-main-surface-side connection terminals having a smaller area.

8. The multilayer wiring substrate according to claim 1, wherein the via conductors formed in the plurality of resin insulation layers are shaped such that a diameter thereof increases along a direction from the second main surface to the first main surface.

9. The multilayer wiring substrate according to claim 1, wherein the plurality of resin insulation layers are formed of a hardened resin insulation material that is not photocurable.

10. The multilayer wiring substrate according to claim 1, wherein the second main surface has a solder resist film provided thereon and made primarily of a hardened photocurable resin insulation material.

11. The multilayer wiring substrate according to claim 1, wherein a solder resist film made primarily of a hardened photocurable resin insulation material is provided in a region around an IC-chip mounting region on the first main surface.

12. The multilayer wiring substrate according to claim 1,
wherein one type of the plurality of first-main-surface-side connection terminals are IC-chip connection terminals for connection of an IC chip, and an other type of the plurality of first-main-surface-side connection terminals are passive-component connection terminals for connection of a passive component, the passive-component connection terminals being greater in area than the IC-chip connection terminals,
wherein the plurality of second-main-surface-side connection terminals are motherboard connection terminals for connection of a motherboard,
wherein the motherboard connection terminals are greater in area than the IC-chip connection terminals and the passive-component connection terminals, and,
when a surface of a resin insulation layer serving as an outermost layer and exposed as the second main surface is defined as a reference surface, outer surfaces of the motherboard connection terminals protrude from the reference surface.

13. The multilayer wiring substrate according to claim 12,
wherein: each motherboard connection terminal has a trapezoidal cross section; and a contact surface of each motherboard connection terminal in contact with the resin insulation layer is greater in area than an outer surface of each motherboard connection terminal opposite the contact surface.

14. The multilayer wiring substrate according to claim 1,
wherein one type of the plurality of first-main-surface-side connection terminals are IC-chip connection terminals for connection of an IC chip, and an other type of the plurality of first-main-surface-side connection terminals are passive-component connection terminals for connection of a passive component, the passive-component connection terminals being greater in area than the IC-chip connection terminals, and
when a surface of a resin insulation layer serving as an outermost layer and exposed as the first main surface is defined as a reference surface, top surfaces of the passive-component connection terminals protrude from the reference surface, and top surfaces of the IC-chip connection terminals are flush with or protrude from the reference surface.

15. The multilayer wiring substrate according to claim 14,
wherein the passive-component connection terminals are higher in height than the IC-chip connection terminals.
